(19) United States
(12) Patent Application Publication
(10) Pub. No.: US 2010/0140083 A1
(43) Pub. Date: Jun. 10, 2010

(54) Dual Magnetron Sputtering Power Supply And Magnetron Sputtering Apparatus

(75) Inventors: Roel Tietema, SK Venlo (NL); Frank Papa, VK Venlo (NL); Geert Sesink, Ka Heeze (NL); Rene Thomasita, VV Venlo (NL)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hauzer Techno Coating BV, LL Venlo (NL)

(21) Appl. No.: 12/445,565

(22) PCT Filed: Oct. 26, 2007
(86) PCT No.: PCT/EP2007/009326

§ 371 Date: Feb. 12, 2010

(30) Foreign Application Priority Data
Oct. 26, 2006 (EP) 06022396.3

(51) Int. Cl. C23C 14/54; C23C 14/35

(52) U.S. Cl. 204/298.03

(57) ABSTRACT

A dual magnetron sputtering power supply for use with a magnetron sputtering apparatus having at least first and second sputtering cathodes for operation in the dual magnetron sputtering mode, there being a means for supplying a flow of reactive gas to each of said first (1) and second (4) cathodes via first (12) and second (14) flow control valves each associated with a respective one of said first and second cathodes and each adapted to control a flow of reactive gas to the respectively associated cathode, the power supply having, for each of said first and second cathodes a means for deriving a feed-back signal relating to the voltage prevailing at that cathode, a control circuit for controlling the flow of reactive gas to the respectively associated cathode by controlling the respective flow control valve and adapted to adjust the respective flow control valve to obtain a voltage feedback signal from the respective cathode corresponding to a set point value set for that cathode. Also claimed is a magnetron sputtering apparatus in combination with such a power supply.

The present invention relates to a dual magnetron sputtering power supply and to a magnetron sputtering apparatus in combination with or having such a dual magnetron sputtering power supply.

When using magnetron sputtering apparatus problems can arise with so-called target poisoning. For example, with an aluminum cathode and using O₂ as the reactive gas, the cathode is initially clean aluminum. In the presence of reactive O₂ a layer of aluminum oxide forms on the target thus poisoning it. A layer of aluminum oxide also forms on the anode, and this insulating layer means the anode starts to “disappear” so far as the cathode is concerned. By changing the polarity of the power supply to the cathode, which inherently occurs in a dual magnetron sputtering apparatus because an alternating power source is connected between the two cathodes, the oxide film on the one cathode, which was previously an anode, is initially more negative because of the electrons which accumulated on the insulating layer and is more strongly bombarded with ions thus cleaning it, i.e. the partial insulating coating on the cathodes, broken down again by the inert gas ions present in the chamber. The coating of articles placed in the vacuum chamber effectively takes place alternately from the first and second cathodes which are operated anti-phase. When one cathode is operating as a cathode, the other cathode is operating as an anode. The voltage at the cathodes varies with the degree of poisoning of the target, i.e. of the cathode surface.

Dual magnetron sputtering systems are, for example, used in glass coating applications and have two cathodes arranged alongside one another, with a supply of oxygen generally being located between them. The state of the art for a dual magnetron sputtering configuration (as it seems to be done in glass coaters) appears to use a voltage feedback signal to control the reactive gas flow to one of the cathodes in order to keep that cathode at a stable working point. However, it seems to be problematic to achieve such a control over a range of working conditions because of hysteresis in the relationship between the voltage feedback signal and the degree of poiconing of the cathode which is dependent on the reactive gas flow, on the amount of reactive gas which can react with the cathode and the cleaning of the cathode which takes place in alternate half cycles.

The object underlying the present invention is to provide a dual magnetron sputtering power supply and magnetic sputtering apparatus in combination with or having such a dual magnetron sputtering power supply which is able to operate in a stable manner over any desired length of a sputter coating phase, which ensures that the desired balanced operation of sputtering from each of the two cathodes is achieved and leads to a high quality sputtered coating with relatively inexpensive means. Furthermore, it is an object of the present invention to provide a dual magnetron sputtering power supply, and a magnetron sputtering apparatus in combination with or having such a dual magnetron sputtering power supply, which is able to cope with voltage variations at the cathodes arising from the movement of individual articles to be coated and elements of the workpiece support for the articles (the workpiece table) through the space in front of the cathodes. It should also be able to take account of the fact that the vacuum pump used to maintain the vacuum chamber at the required low pressure level inevitably tends to remove more reactive gas from one cathode than the other cathode for symmetry reasons.

In order to satisfy this object there is provided, in accordance with the present invention, a dual magnetron sputtering power supply for use with a magnetron sputtering apparatus having at least first and second sputtering cathodes for operation in the dual magnetron sputtering mode, there being an AC power supply connected to the first and second sputtering cathodes, a means for supplying a flow of reactive gas to each of said first and second cathodes via first and second flow control valves each associated with a respective one of said first and second cathodes and each adapted to control a flow of reactive gas to the respectively associated cathode, the power supply having, for each of said first and second cathodes, a means for deriving a feedback signal relating to the voltage prevailing at that cathode, a control circuit for controlling the flow of reactive gas to the respectively associated cathode by controlling the respective flow control valve and adapted to adjust the respective flow control valve to obtain a voltage feedback signal from the respective cathode corresponding to a set point value set for that cathode.

By providing a dual magnetron sputtering power supply of this kind it is possible to control the flow of the reactive gas to each of the cathodes, by controlling the respective flow control valves for the supply of reactive gas to each said cathode in such a way that balanced operation of a magnetron sputtering apparatus is achieved and thus a stable working point. Because each cathode becomes slightly poisoned during one half cycle of the AC power supply and is then partially cleaned again during the next half cycle, it is desirable to achieve an average degree of poisoning of each cathode which remains constant over many cycles of an AC power supply and indeed preferably for the degree of poisoning of each cathode to be the same, and indeed taking automatic account of the possible asymmetry of the removal of reactive gases from the vicinity of each of the cathodes by the vacuum pump associated with the apparatus. The above recited system makes it possible to achieve this end.

Preferred embodiments of the invention are set forth in the subordinate claims. It is particularly expeditious to measure the voltage prevailing at each of the cathodes with reference to earth or ground because this provides voltage feedback signals related to a common reference point (ground).

In a particularly preferred embodiment the control circuit comprises a respective regulator or controller for each cathode having as inputs the feedback signals from the cathodes and respective set point signals and producing as outputs a respective partial pressure set point signal, wherein a respective probe respectively associated with each cathode generates an actual pressure signal of the reactive gas, wherein the partial pressure set point signals and the respective actual pressure signals are applied to respective inputs of further regulators or controllers, the respective output signals of which serve to generate actuation signals for actuating the flow control valves supplying reactive gas to the respectively associated cathodes. That is to say there are nested voltage and partial pressure control loops which result in a high quality control of the dual magnetron sputtering apparatus so that very stable operation can be maintained at each of the two cathodes with the desired composition of the sputtered coating being obtained.

The present invention will now be explained in more detail with reference to the embodiments and to the accompanying drawings in which are shown:

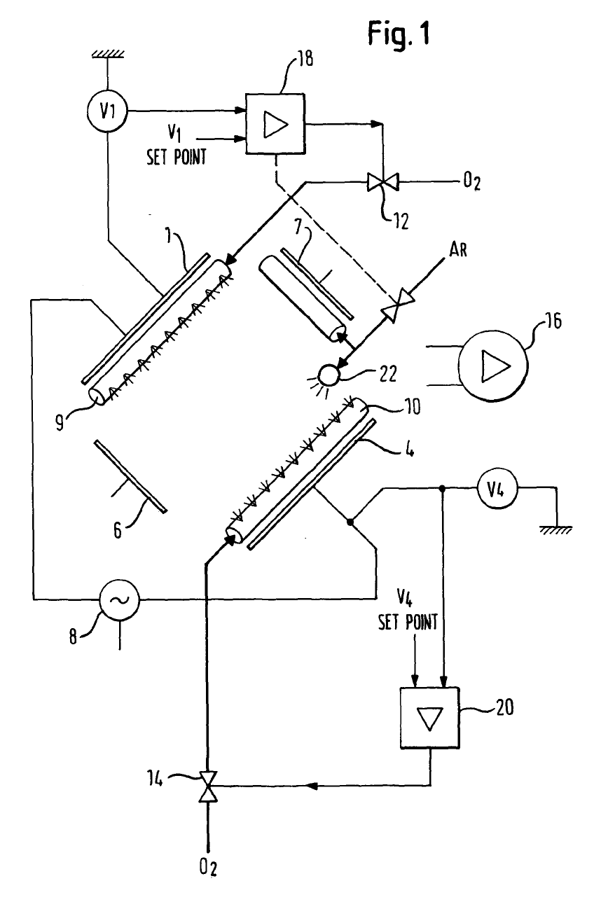

FIG. 1 a first practical embodiment of a dual magnetron sputtering power supply in accordance with the present invention shown in schematic form,

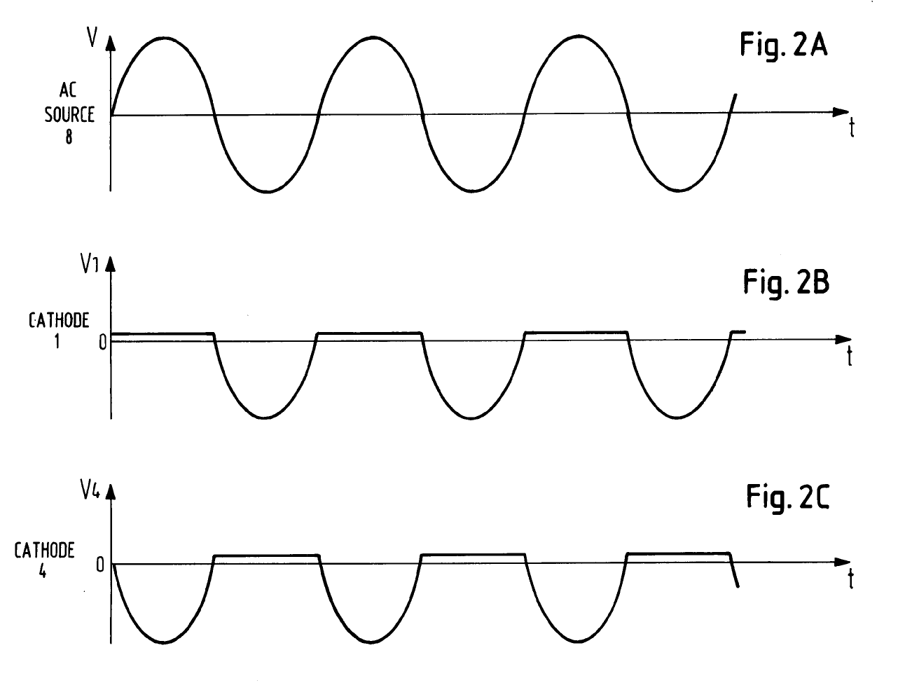

FIGS. 2A to 2C diagrams to explain the voltages present at two cathodes (cathode 1, FIG. 2B and cathode 4, FIG. 2C) fed in a magnetron sputtering apparatus by an AC voltage in accordance with FIG. 2A which is applied between them,

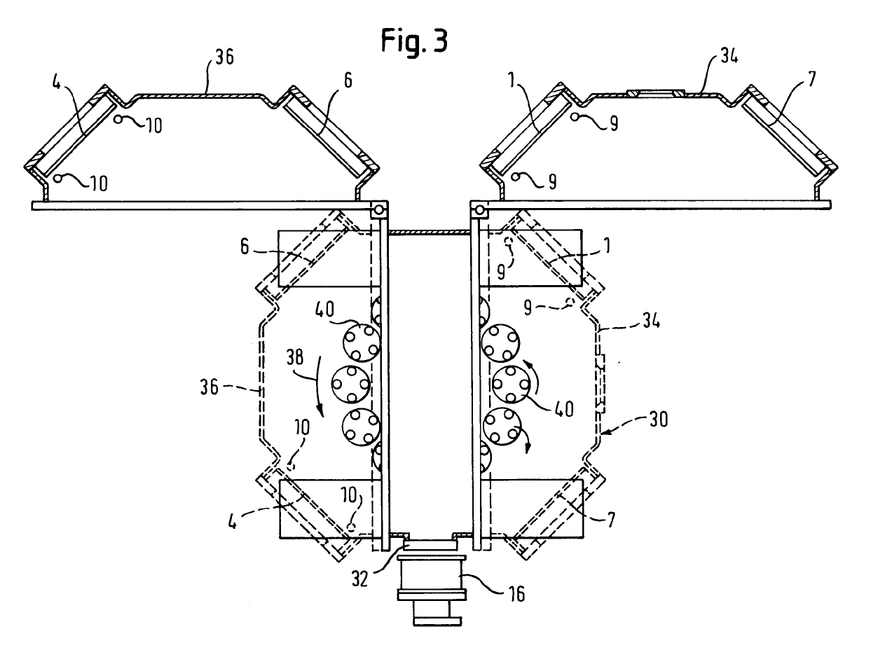

FIG. 3 a schematic diagram to illustrate the layout of a magnetron sputtering apparatus and to further explain the asymmetry of the removal of reactive gas from the vacuum chamber by the vacuum pump, and

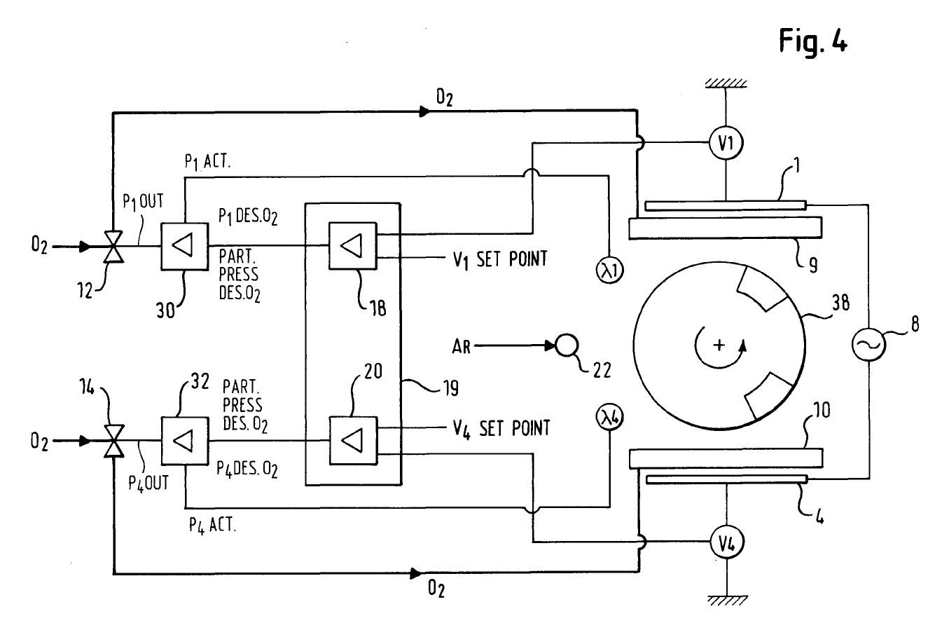

FIG. 4 a preferred embodiment of the dual magnetron sputtering power supply in accordance with the present invention.

Turning now to FIG. 1, the attached drawing shows a dual magnetron sputtering power supply (DMS) in accordance with the present invention, as defined in the claims, The dual magnetron sputtering power supply is connected to first and second cathodes 1 and 4. The cathodes 1 and 4 are located with other cathodes 6 and 7 and optionally with further arc cathodes or magnetron cathodes (not shown) in a vacuum chamber (also not shown) and can be operated from an AC power supply 8 which usually is connected as shown in FIG. 1 so that alternating operation of the two generally opposed cathodes is achieved. Each of the first and second cathodes 1 and 4 is equipped with a respective gas frame 9, 10 for the supply of reactive gas at an inlet near the respective cathode. The cathodes 1 and 4 are connected to the DMS (Dual Magnetron Sputtering Power Supply).

The cathodes may be, but do not necessarily need to be opposed to each other. State of the art for a DMS configuration (as it seems to be done in glass coaters) is that a voltage feedback signal controls the reactive gas flow (here: O₂ flow) to cathode 1, in order to keep the cathode at a stable working point (see literature of Bill Sproul on IRESS). The O₂ flow to the second cathode 4 is controlled in the prior art by an Optical Emission Controller.

In contrast, in accordance with the present invention, a feedback signal (“V1-signal”) from first cathode 1 voltage (or from the DMS power supply) is used for control of a first O₂ inlet valve 12 at the first cathode 1, whereas control of a second O₂ inlet valve at the second cathode 4 is governed by the feedback signal (“V4-signal”) of the second cathode 4 voltage. These are separate transmitters of voltage, measuring AC apparent voltage, AC rectified voltage or DC voltage. The elements shown in the drawing by symbols have their usual meaning. Thus, the triangle in a circle 16 represents the vacuum pump for producing the required operating vacuum in the chamber and the triangle in a square symbol signifies a feedback controlled regulator 18, 20 respectively.

In both cases the O₂-flow is increased until the respective cathode voltage reaches the set point value V_{1 SET POINT} and V_{4 SET POINT} respectively corresponding to the requirement of the control system. This set point value is generally chosen to be a DC voltage but it could also be a profiled, time dependent voltage. For O₂ this value is lower than the voltage in metallic (non-reactive) mode, at least when the cathodes are made of Al for forming, e.g., an Al₂O₃ coating. For other gas/metal combinations this might be a higher value.

The argon (Ar) flow for sputtering (non-reactive sputter gas) is supplied at a different place 22 than the O₂ inlet (in general this is the state of the art), but it could also be supplied near the cathode, e.g. at 22′, or combined near the cathode. It can also be supplied at one of the other cathodes or centrally or at any other appropriate place in or adjacent to the vacuum chamber or system.

The control system is preferably realized with fast response MFC's (mass flow controllers), i.e. 18, 20, for reactive sputtering of oxygen or other difficult to sputter materials with a fairly big voltage difference between the metallic mode and the fully poisoned reactive mode. The problem of target poisoning is one of the prime reasons for using a dual mode magnetron sputtering system. For example, with an Al cathode and using O₂ as the reactive gas the cathode is initially clean aluminum. In the presence of reactive O₂ a layer of aluminum oxide forms on the target thus poisoning it. By changing the polarity of the power supplied to the cathode, inherent in DMS, the oxide film is broken down again by the inert gas ions in the chamber. Thus the coating of articles placed in the vacuum chamber effectively takes place alternately from the first and second cathodes which are operated antiphase. The voltage at the cathodes varies with the degree of poisoning of the target (cathode surface).

Turning now to FIGS. 2A to 2C, an explanation can be given of how the sinusoidal wave form generated by the AC power source 8 as shown in FIG. 2A relates to the voltages at the two cathodes 1 and 4.

Because the two cathodes 1 and 4 are connected to respective output terminals of the AC source and because the conditions inside the vacuum chamber means that this acts as a rectifier diode, the voltage at the cathodes 1 and 4 in each case corresponds to a negative half wave of the sinusoidal supply, with the two half waves being shifted relative to one another by 180° as shown in FIGS. 2B and 2C. Because of the rectifying action of the magnetron sputtering apparatus, which operates in both directions, i.e. the polarity of the effective anode is reversed each half cycle, the voltage at the cathodes during the positive half phases is only slightly above zero and the cathode acts during this part of the cycle as an anode. Thus, during the negative half waves, the cathodes 1 and 4 act as cathodes, in the periods in between they act as anodes with a small anode voltage. When they are acting as cathodes, during the negative half cycles, reactive sputtering takes place from the respective cathode and the cathode surface is cleaned. During the period the respective cathodes act as an anode, i.e. each alternate half cycle, sputtered material accumulates on them, i.e. insulating material and this accumulated material is subsequently removed again during the next negative half cycle when the respective cathode is acting as a sputtering cathode. Thus, although the cathodes become contaminated, they are cleaned again during each half cycle in which they are acting as sputtering cathodes the desired reactive sputtering takes place, with it being possible to keep the average degree of poisoning at each cathode 1, 4 constant over a long period of time.

It should be noted that the peak negative amplitude of the voltage present at the cathodes 1 and 4 as shown in FIGS. 2B and 2C is generally desirably the same at each cathode, but is less than the open circuit output of the AC source 8 because of the average degree of target poisoning.

Turning now to FIG. 3 there can be seen a schematic drawing of a magnetron sputtering apparatus having a chamber 30 of generally octagonal shape in the traditional form used by Hauzer Techno Coating BV. The chamber has a central portion 32 and two large hinged doors 34, 36 which each include two elongate, generally rectangular cathodes 1, 7 and 4, 6, which can thus be easily accessed for maintenance and exchange. The long sides of the rectangular cathodes are perpendicular to the plane of the drawing. Associated with each cathode 1, 7, 4, 6 is, in the usual way, a system of magnets (permanent magnets and/or magnetic coils) which generate the magnetic field necessary for magnetron operation. These magnet systems are not shown in any of the drawings of this application, and indeed this is not necessary because they are well understood by a person skilled in the art.

The pivotally mounted doors 34, 36 can be pivoted into the position shown in broken lines to close the chamber in use. The chamber typically has a generally octagonal base and octagonal cover which seal the chamber so that a vacuum can be generated therein by the vacuum pump 16. Within the chamber there is usually a rotary table 28 which carries workpieces either directly or on further smaller rotary tables 40 which rotate about their own axes as well as rotating with the table 38 about the central vertical axis of the chamber.

It can be seen from FIG. 3 that the cathode 4 is closer to the vacuum pump 16 than the cathode 1, i.e. the generally opposed cathodes 1, 4 are asymmetrically arranged with respect to the vacuum pump 16 and this means that the vacuum pump 16 will tend to extract more reactive gas from the vicinity of the cathode 4 than from the vicinity of the cathode 1 and this has to be compensated by increasing the supply of reactive gas via a respective gas frame 10 associated with the cathode 4 relative to the supply of reactive gas supplied via the gas frame 9 associated with the cathode 1.

Turning now to FIG. 4, a preferred embodiment of the dual magnetron sputtering power supply in accordance with the present invention will now be described. In this Figure, some reference numerals are common to the reference numerals used in FIG. 1 and it will be understood that these reference numerals refer to the same items as in FIG. 1 and that the same description applies unless something is specifically stated to the contrary. Again in FIG. 4 the vacuum chamber is not shown for the sake of simplicity.

Again, the magnet systems associated with the cathodes 1 and 4 are not shown and also relative to FIG. 1 the further cathodes such as 6 and 7 have been omitted. The workpiece table 38, i.e. the table which carries the workpieces, is schematically illustrated between the opposed cathodes 1 and 4 as are the gas frames 9 and 10 associated with the respective cathodes. It should be noted that the gas frames do not necessarily have to extend around all four sides of the rectangular cathodes but typically extend along the two longitudinal sides of the elongate rectangular cathodes as shown by the drawings of FIGS. 1, 3 and 4. The idea is to obtain a uniform gas distribution in front of the cathodes.

FIG. 4 shows, in distinction to FIG. 1, first and second lambda sensors, λ₁ and λ₄, which are arranged in the proximity of the cathodes 1 and 4 and of the gas frames 9 and 10 and which serve to measure the partial pressure of the reactive gas, in this case oxygen. If the reactive gas is a different gas, for example nitrogen, then obviously other probes have to be used which are sensitive to the concentration of the reactive gas being used.

In the embodiment of FIG. 4, as in the embodiment of FIG. 1, the voltage of each cathode relative to ground is measured and respective voltage signals V1 and V4, which comprise the actual voltage signals, are supplied to respective regulators 18 and 20 which can, for example, be completely separate regulators or can be integrated into a common control system as indicated by the block in FIG. 4. This can, for example, be a sps controller or regulator system 19 as well known per se. Each of the two regulators or controllers 18 and 20 receives a set point signal V_{1SETPOINT}, V_{4SETPOINT} for the respective voltages V1 and V4, which can either be fixed voltages or can have a specific voltage profile desired for a particular operation. The controllers or regulators 18 thus each compare the actual measured voltage V1 and V4 with the respective set point voltage V_{1SETPOINT} and V_{4SETPOINT} respectively and produce an output signal which represents a desired partial pressure signal for the reactive gas, in this case O₂, in the vicinity of the respective cathode 1 or 4. The values of V_{1SETPOINT} and V_{4SETPOINT} are generally the same as each other. The signals from the two lambda sensors, λ₁ and λ₄, provide a signal proportional to the actual partial pressure P_{1ACT} and P_{4ACT} respectively present in the vicinity of the cathodes 1 and 4. The boxes labeled 30 and 32 represent further regulators or controllers which then compare the desired partial pressure signals abbreviated P_{1DES.}O₂ and P_{4DES.}O₂, with the actual pressure signals P_{1ACT} and P_{4ACT} and produce output signals P_{1OUT} and P_{2OUT} which control the mass flow control flows 12 and 14 used to control the flow of the reactive gas, in this example O₂, to the respective gas frames 9 and 10. The input lines to the gas flow controllers 12 and 14 can come from a common source and they are simply schematically shown as if they come from different sources in FIG. 4.

In a dual mode magnetron sputtering system having workpieces on a movable workpiece table 38 there is a significant tendency for electrons in the vicinity of the cathodes 1 and 4 to be affected by gaps which appear on rotation of the workpiece table in such a way that they may tend to move to the other respective cathode when acting as an anode and thus result in fluctuation of the voltage signals V₁ and V₄. The regulators or controllers 18, 20 are selected to be relatively slow regulators so that they tend to smooth out voltage fluctuations and maintain the voltages V₁ and V₄ measured at the respective cathodes 1 and 4 within preselected bandwidths. Thus, fluctuations of the voltages V₁ and V₄ do not lead to instabilities in operation.

As stated earlier, the output signals of the regulators or controller 18, 20 are used as desired partial pressure signals for the partial pressures of the reactive gas present in the vicinity of the cathodes 1 and 4. The action of the output signals P_{1OUT} and P_{4OUT} of the further regulators 30 and 32 on the mass flow controllers 12 or 14 thus tries to correct the supply of reactive gas to the respective cathodes 1 and 4 so that the actual pressure values P_{1ACT} and P_{4ACT} correspond as closely as possible to the partial pressure desired signals P_{1DES.}O₂ and P_{4DES.}O₂. The respective partial pressures set in this way in turn vary the voltage feedback signals V₁ and V₄ and thus permit correction of the conditions prevailing at the cathodes 1 and 4 so that these are operated at or close to the desired set point values V_{1SETPOINT} and V_{4SETPOINT} respectively.

Although the further regulators 30 and 32 are described as hard regulators in the sense that they react quickly to changes of the desired partial pressures P_{1DES} and P_{4DES}, it is believed that these could also be realized as soft regulators without significant disadvantage.

It should be noted that when using lambda sensors the character of the feedback signal means that a decrease of the set point value physically relates to an increase of the partial pressure (for example in mbar).

So the actual pressures are sensed as samples and after each sampling interval a change of a set point can occur. The precise layout of the controls can include multiplication of signals with predefined values to improve the control response and to ensure that the system operates within the preset bandwidths.

It should also be noted that it is possible to build in alarms into the system such that if operating parameters move outside of the preset bandwidths an alarm signal is generated and optionally some other step is automatically taken to overcome the difficulty, for example shutdown of the apparatus until the reason for the alarm has been diagnosed and remedied.

1-22. (canceled)

23. A dual magnetron sputtering power supply for use with a magnetron sputtering apparatus having at least first and second sputtering cathodes (1, 4) for operation in a dual magnetron sputtering mode, there being an AC power supply (8) connected to the first and second sputtering cathodes (1, 4), a means (9, 10) for supplying a flow of reactive gas to each of said first and second cathodes (1, 4) via first and second flow control valves (12, 14) each associated with a respective one of said first and second cathodes (1, 4) and each adapted to control a flow of reactive gas to the respectively associated cathode, the power supply having, for each of said first and second cathodes, a means for deriving a feedback signal (V₁, V₄) relating to the voltage prevailing at that cathode (1, 4), a control circuit (18, 20) for controlling the flow of reactive gas to the respectively associated cathode (1, 4) by controlling the respective flow control valve (12, 14) and adapted to adjust the respective flow control valve (12, 14) to obtain a voltage feedback signal (V₁, V₄) from the respective cathode (1, 4) corresponding to a set point value (V_{1 SET POINT}, V_{4 SET POINT}) set for that cathode, wherein said control circuit (18, 20) comprises a respective regulator for each cathode having as inputs the feedback signals (V₁, V₄) from the cathodes (1, 4) and respective set point signals (V_{1 SET POINT}, V_{4 SET POINT}) and producing as outputs a respective partial pressure set point signal (P_{1 DES.} and (P_{4 DES.}), wherein a respective probe (λ₁, λ₄) respectively associated with each cathode (1, 4) generates an actual pressure signal of the reactive gas (P_{1ACT}, P_{4ACT}), wherein the partial pressure set point signals (P_{1 DES.}, P_{4 DES.}) and the respective actual pressure signals (P_{1ACT}, P_{4ACT}) are applied to respective inputs of further regulators (30, 32), the respective output signals of which serve to generate actuation signals (P_{1OUT} and P_{4OUT}) for actuating the flow control valves (12, 14) supplying reactive gas to the respectively associated cathodes (1, 4).

24. A dual magnetron sputtering power supply in accordance with claim 23, wherein the reactive gas is supplied via the respective flow control valve (12, 14) to each of said first and second cathodes (1, 4) via a gas frame respectively associated with that cathode (1, 4).

25. A dual magnetron sputtering power supply in accordance with claim 23, wherein the voltage feedback signal (V₁, V₄) for each of said first and second cathodes (1, 4) is one of a voltage measuring device for measuring the apparent AC voltage applied to each respective cathode, or for measuring a rectified AC voltage or for measuring a related DC voltage or for tapping the output voltage supplied by the power supply (8) to the respective cathode (1, 4).

26. A dual magnetron sputtering power supply in accordance with claim 23, wherein the said first and second cathodes (1, 4) are opposed cathodes of the magnetron sputtering apparatus.

27. A dual magnetron sputtering power supply in accordance with claim 23, wherein the cathode material of each of said first and second cathodes (1, 4) is selected from the group including metals such as aluminum or titanium, semiconductors such as silicon and mixtures of any of the foregoing and in that the reactive gas is selected from the group including oxygen and nitrogen.

28. A dual magnetron sputtering power supply in accordance with claim 23 in which an inert gas (Ar) is supplied to the vacuum chamber at another cathode or at a central feed point (22) in the vacuum chamber or at any other appropriate point in or adjacent the vacuum chamber.

29. A dual magnetron sputtering power supply in accordance with claim 23, wherein each said feedback signal (V₁, V₄) is measured between the respective cathode and ground.

30. A dual magnetron sputtering power supply in accordance with claim 23, wherein each said control circuit (18, 20) is a slow regulator relative to the frequency of the applied feedback signal (V₁, V₄).

31. A dual magnetron sputtering power supply in accordance with claim 23, wherein said further regulators (30, 32) are hard regulators.

32. A dual magnetron sputtering power supply in accordance with claim 23, wherein said further regulators (30, 32) are soft regulators.

33. A dual magnetron sputtering power supply in accordance with claim 23, wherein said reactive gas is O₂ and said probes are Lambda sensors (λ₁, λ₄).

34. A dual magnetron sputtering power supply in accordance with claim 23, wherein said AC power supply generates AC power in the kHz frequency range.

35. A dual magnetron sputtering power supply in accordance with claim 34, wherein said AC power supply generates AC power in the frequency range 40 to 60 kHz.

36. A dual magnetron sputtering power supply in accordance with claim 23, wherein the respective output voltage (V₁, V₄) at each cathode is a rectified AC voltage typically in the range 50 to 400 volts.

37. A dual magnetron sputtering power supply in accordance with claim 23 in which a regulator is provided for regulating the inert gas supply to maintain the total pressure in the chamber substantially constant irrespective of changes in the partial pressures of the reactive gas supplied to the respective cathodes (1, 4).

38. A dual magnetron sputtering power supply in accordance with claim 23 in which a regulator is provided for regulating the inert gas supply to maintain the inert gas pressure in the chamber substantially constant.

39. A dual magnetron sputtering power supply in accordance with claim 23, wherein the power dissipated at each of the cathodes (1, 4) is substantially the same over a plurality of cycles of said AC power supply, i.e. over a period of time.

40. A dual magnetron sputtering power supply in accordance with claim 23, wherein the reactive gas is supplied to each said first and second cathode (1, 4) via a respective gas frame.

41. A dual magnetron sputtering power supply in accordance with claim 23, wherein voltage set point signals (V_{1 SET POINT} and V_{4 SET POINT}) are equal to each other at any point in time.

42. A dual magnetron sputtering power supply in accordance with claim 23, wherein said voltage set point signals (V_{1 SET POINT} and V_{4 SET POINT}) are variable with respect to time.

43. A magnetron sputtering apparatus in combination with or having a dual magnetron sputtering power having at least first and second sputtering cathodes (1, 4) for operation in a dual magnetron sputtering mode, there being an AC power supply (8) connected to the first and second sputtering cathodes (1, 4), a means (9, 10) for supplying a flow of reactive gas to each of said first and second cathodes (1, 4) via first and second flow control valves (12, 14) each associated with a respective one of said first and second cathodes (1, 4) and each adapted to control a flow of reactive gas to the respectively associated cathode, the power supply having, for each of said first and second cathodes, a means for deriving a feedback signal (V₁, V₄) relating to the voltage prevailing at that cathode (1, 4), a control circuit (18, 20) for controlling the flow of reactive gas to the respectively associated cathode (1, 4) by controlling the respective flow control valve (12, 14) and adapted to adjust the respective flow control valve (12, 14) to obtain a voltage feedback signal (V₁, V₄) from the respective cathode (1, 4) corresponding to a set point value (V_{1 SET POINT}, V_{4 SET POINT}) set for that cathode, wherein said control circuit (18, 20) comprises a respective regulator for each cathode having as inputs the feedback signals (V₁, V₄) from the cathodes (1, 4) and respective set point signals (V_{1 SET POINT}, V_{4 SET POINT}) and producing as outputs a respective partial pressure set point signal (P_{1 DES.} and P_{4 DES.}), wherein a respective probe (λ₁, λ₄) respectively associated with each cathode (1, 4) generates an actual pressure signal of the reactive gas (P_{1ACT}, P_{4ACT}), wherein the partial pressure set point signals (P_{1 DES.}, P_{4 DES.}) and the respective actual pressure signals (P_{1ACT}, P_{4ACT}) are applied to respective inputs of further regulators (30, 32), the respective output signals of which serve to generate actuation signals (P_{1OUT} and P_{4OUT}) for actuating the flow control valves (12, 14) supplying reactive gas to the respectively associated cathodes (1, 4).
